(19) United States
(12) Patent Application Publication
(10) Pub. No.: US 2005/0179078 A1
(43) Pub. Date: Aug. 18, 2005

(54) Non-volatile memory devices including high-voltage transistors and methods of fabricating the same

(76) Inventor: Chang-Hyun Lee, Gyeonggi-do (KR)

Correspondence Address: MYERS BIGEL SIBLEY & SAJOVEC, PO BOX 37428, RALEIGH, NC, 27627, US

(21) Appl. No.: 11/011,015

(22) Filed: Dec. 13, 2004

(30) Foreign Application Priority Data
Feb. 17, 2004 (KR) 2004-10463

(51) Int. Cl. H02M 5/42; H01L 21/336; H01L 29/76; H01L 31/062

(52) U.S. Cl. 257/314; 257/392; 438/257; 438/275

(57) ABSTRACT

Non-volatile memory devices are provided including a cell array having a word line and a bit line. A row decoder is coupled to the word line and configured to apply word line voltages to the word line. A first high voltage transistor is coupled to the row decoder and is configured to control the word line voltages. A reading/writing circuit is coupled to the bit line and configured to apply bit line voltages to the bit line. A second high voltage transistor is coupled to the reading/writing circuit and is configured to control the bit line voltages, such that a saturation current output per a unit channel width of the second high-voltage transistor is larger than that of the first high-voltage transistor when a first word line voltage is the same as a first bit line voltage. Related methods of fabricating non-volatile memory devices are also provided.

### CLAIM OF PRIORITY

This application is related to and claims priority from Korean Patent Application No. 2004-10463, filed on Feb. 17, 2004, the disclosure of which is hereby incorporated herein by reference as if set forth in its entirety.

### FIELD OF THE INVENTION

The present invention relates to semiconductor devices and methods of fabricating the same and, more particularly, to non-volatile memory devices and methods of fabricating the same.

### BACKGROUND OF THE INVENTION

Non-volatile memory devices, such as flash memory devices, are capable of storing data when power is removed from the semiconductor device. A unit cell of a flash memory device may include an electrically isolated floating gate, source and drain regions on a substrate on first and second sides of the floating gate, respectively, and a control gate electrode that is configured to control the floating gate. Typically, a threshold voltage of a flash memory cell depends on an amount of electric charge stored in the floating gate. Data stored in the flash memory cell can be detected by sensing a variation of an amount of cell current of the flash memory cell due to a difference in the threshold voltage.

When data is written to and/or erased from the flash memory cell, high voltages relative to a power voltage Vcc are typically used. In a write and/or erase operation, charges may be injected into the floating gate or withdrawn from the floating gate by tunneling an insulating layer surrounding the floating gate.

Typically, a control gate electrode of a flash memory cell is electrically coupled to a word line and a drain region of the flash memory cell is electrically coupled to a bit line. The word line is electrically coupled to a row decoder and the bit line is electrically coupled to a reading/writing circuit. The row decoder may be configured to select one of a plurality of word lines and may apply word line voltages to the selected word line. The word line voltages are voltages applied to a word line for performing writing, reading and/or erasing operations. The reading/writing circuit is configured to select one of a plurality of bit lines and may apply bit line voltages to the selected bit line. The bit line voltages are voltages applied to a bit line for performing the writing, erasing and/or reading operations. Furthermore, the reading/writing circuit may output data of a flash memory cell, also electrically coupled to the selected word line and the selected bit line, through the selected bit line. The row decoder typically includes at least one first high-voltage transistor configured to control the word line voltages, and the reading/writing circuit typically includes at least one second high-voltage transistor configured to control the bit line voltages.

In conventional flash memory devices, the first high-voltage transistor can sustain the word line voltages. In other words, the first high-voltage transistor should have a punch-through characteristic that can sustain the word line voltages. Similarly, the second high-voltage transistor can sustain the bit line voltages. Furthermore, in order to secure a sensing margin of the flash memory device, the second high-voltage transistor may have a sufficiently high amount of output current. By providing a sufficient current amount to the selected bit line, it may be possible to sense a variation of the amount of current provided to the selected bit line according to data stored in the selected cell.

As the speed of semiconductor devices continues to increase, the amount of output current of the second high-voltage transistor may become more difficult to maintain. Furthermore, as semiconductor devices become more highly integrated, non-volatile memory devices have also become more highly integrated.

### SUMMARY OF THE INVENTION

Some embodiments of the present invention provide non-volatile memory devices including a cell array having a word line and a bit line. A row decoder is coupled to the word line and configured to apply word line voltages to the word line. A first high voltage transistor is coupled to the row decoder and is configured to control the word line voltages. A reading/writing circuit is coupled to the bit line and configured to apply bit line voltages to the bit line. A second high voltage transistor is coupled to the reading/writing circuit and is configured to control the bit line voltages, such that a saturation current output per a unit channel width of the second high-voltage transistor is larger than that of the first high-voltage transistor when a first word line voltage is the same as a first bit line voltage.

In further embodiments of the present invention, the row decoder may be further configured to apply the word line voltages to the word line in a writing, an erasing and/or a reading mode. The reading/writing circuit may be further configured to apply the bit line voltages to the bit line in the writing, the erasing and/or the reading mode. In certain embodiments of the present invention, a maximum value of absolute values of the bit line voltages may be less than a maximum value of absolute values of the word line voltages and the maximum value of absolute values of the bit line voltages may be greater than a power voltage.

In still further embodiments of the present invention, an integrated circuit substrate may be provided. The first high-voltage transistor may include a first high-voltage gate insulating layer and a first high-voltage gate electrode sequentially stacked on the integrated circuit substrate. A first source region may be on the integrated circuit substrate on a first side of the first high-voltage gate electrode and a first drain region may be provided on the integrated circuit substrate on a second side of the first high-voltage gate electrode. The first source region and the first drain region may have a first low-concentration diffusion layer and a first high concentration diffusion layer. The second high-voltage transistor may include a second high-voltage gate insulating layer and a second high-voltage gate electrode sequentially stacked on the integrated circuit substrate. A second source region may be provided on the integrated circuit substrate on a first side of the second high-voltage gate electrode. A second drain region may be provided on the integrated circuit substrate on a second side of the second high-voltage gate electrode. The second source region and the second drain region may have a second low-concentration diffusion layer and a second high concentration diffusion layer. A width of the second low-concentration diffusion layer may be narrower than a width of the first low-concentration diffusion layer.

In some embodiments of the present invention, a first spacer may be provided on sidewalls of the first high-voltage gate electrode. A second spacer may be provided on sidewalls of the second high-voltage gate electrode. The widths of the first and second low-concentration diffusion layers may be wider than the widths of bottom surfaces of the first and second spacers.

In further embodiments of the present invention, a first spacer may be provided on sidewalls of the first high-voltage gate electrode and a second spacer may be provided on sidewalls of the second high-voltage gate electrode. The width of the first low-concentration diffusion layer may be wider than a width of a bottom surface of the first spacer. The second low-concentration diffusion layer may be aligned to a bottom surface of the second spacer.

In still further embodiments of the present invention, a first spacer may be provided on sidewalls of the first high-voltage gate electrode and a second spacer may be provided on sidewalls of the second high-voltage gate electrode. A width of a bottom surface of the first spacer may be wider than a width of a bottom surface of the second spacer. The first and second low-concentration diffusion layers may be aligned to the bottom surfaces of the first and second spacers.

In some embodiments of the present invention, the second high-voltage gate insulating layer may be thinner than the first high-voltage gate insulating layer. Certain embodiments of the present invention further include a low-voltage gate insulating layer and a low-voltage gate electrode sequentially stacked on the integrated circuit substrate. A third source region may be provided on the integrated circuit substrate on a first side of the low-voltage gate electrode. A third drain region may be provided on the integrated circuit substrate on a second side of the low-voltage gate electrode. The third source region and the third drain region may have a third low-concentration diffusion layer and third high-concentration diffusion layer. A width of the second low-concentration diffusion layer is wider than a width of the third low-concentration diffusion layer. The first high-voltage transistor may include a first high-voltage gate insulating layer and a first high-voltage gate electrode sequentially stacked on the integrated circuit substrate. The second high-voltage transistor may include a second high-voltage gate insulating layer and a second high-voltage gate electrode sequentially stacked on the integrated circuit substrate. The second high-voltage gate insulating layer may be thinner than the first high-voltage gate insulating layer.

While the present invention is described above primarily with reference to non-volatile memory devices, methods of fabricating non-volatile memory devices are also provided herein.

### BRIEF DESCRIPTION OF THE DRAWINGS

FIG. 1 is a circuit diagram of non-volatile memory devices according to some embodiments of the present invention.

FIG. 2A is a cross section illustrating non-volatile memory devices according to further embodiments of the present invention.

FIG. 2B is a cross section illustrating non-volatile memory devices according to still further embodiments of the present invention.

FIG. 2C is a cross section illustrating non-volatile memory devices according to some embodiments of the present invention.

FIGS. 3A to 3C are cross sections illustrating processing steps in the fabrication of non-volatile memory devices illustrated in FIG. 2A.

FIGS. 4A to 4C are cross sections illustrating processing steps in the fabrication of non-volatile memory devices illustrated in FIG. 2B.

FIGS. 5A to 5C are cross sections illustrating processing steps in the fabrication of non-volatile memory devices illustrated in FIG. 2C.

FIG. 6 is a cross section illustrating non-volatile memory devices according to some embodiments of the present invention.

FIGS. 7A to 7B are cross sections illustrating processing steps in the fabrication of non-volatile memory devices illustrated in FIG. 6.

### DETAILED DESCRIPTION OF EMBODIMENTS OF THE PRESENT INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items. Like numbers refer to like elements throughout.

It will be understood that although the terms first and second are used herein to describe various regions, layers and/or sections, these regions, layers and/or sections should not be limited by these terms. These terms are only used to distinguish one region, layer or section from another region, layer or section. Thus, a first region, layer or section discussed below could be termed a second region, layer or section, and similarly, a second region, layer or section may be termed a first region, layer or section without departing from the teachings of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the precise shape of a region of a device and are not intended to limit the scope of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

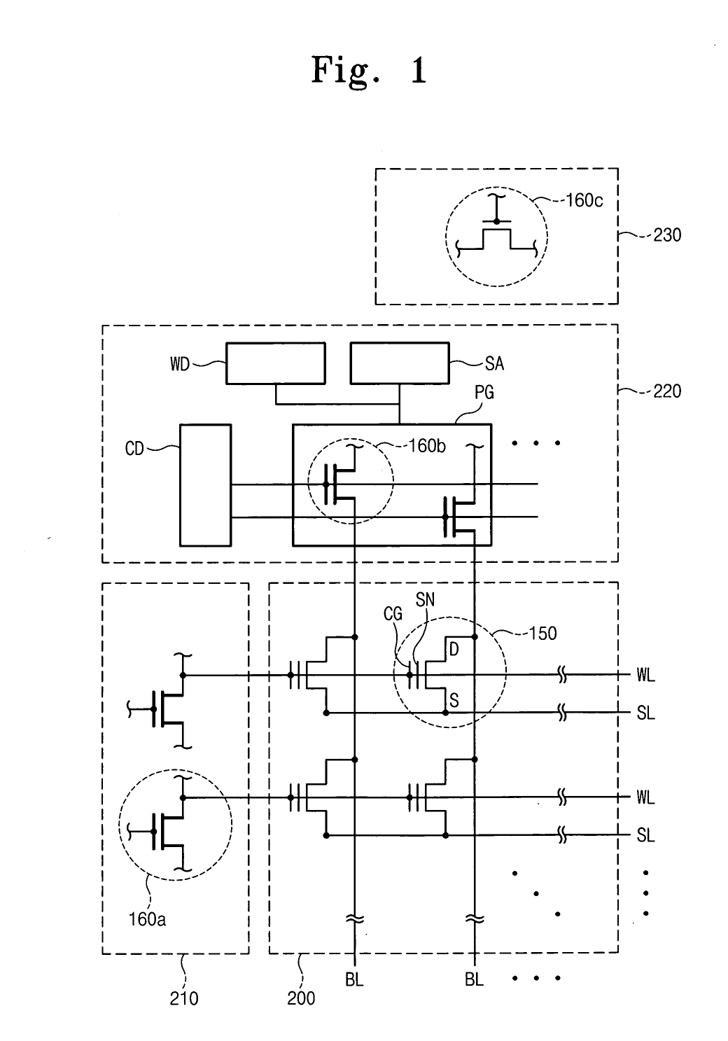

Embodiments of the present invention will now be discussed with respect to FIGS. 1 through 7B. Referring now to FIG. 1, an equivalent circuit of non-volatile memory devices according to some embodiments of the present invention will be discussed. Non-volatile memory devices according to some embodiments of the present invention may be, for example, NOR-type non-volatile memory devices as illustrated in FIG. 1.

As illustrated in FIG. 1, non-volatile memory devices according to some embodiments of the present invention include a cell array region 200, a row decoder 210, a reading/writing circuit 220 and a low voltage circuit 230. The cell array region 200 includes a plurality of non-volatile memory cells 150 that are arranged in a matrix format of rows and columns. As further illustrated in FIG. 1, a plurality of word lines WL and a plurality of bit lines BL are arranged in the cell array region 200. The plurality of word lines WL and the plurality of bit lines BL are arranged in a line along the row direction and the column direction, respectively. The non-volatile memory cell 150 includes a control gate electrode CG, a storage node SN, a source region S and a drain region D.

The storage node may be electrically isolated and charges may be stored therein. In some embodiments of the present invention, the storage node SN may be, for example, a floating gate and, therefore, the stored charges may be free-charges. In further embodiments of the present invention, the storage node SN may be, for example, a trap insulating layer containing a large quantity of deep level traps. Charges may be stored in the deep level traps. Furthermore, in some embodiments of the present invention, the non-volatile memory cell 150 may be, for example, a multi-level cell capable of storing several bits of data. In these embodiments of the present invention, the non-volatile memory cell 150 can store several bits of data according to the amount of charges stored at the storage node SN.

As further illustrated in FIG. 1, the control gate electrode CG of the non-volatile memory cell 150 is electrically coupled to the word line WL, the drain region D is electrically coupled to the bit line BL and the source region S is connected to a source line SL. The source line SL may be substantially parallel to the word line WL. Each of the non-volatile memory cells 150 arranged in each row direction may be commonly coupled to one word line WL and one source line, and each of the non-volatile memory cells 150 arranged in each column direction may be commonly coupled to one bit line BL.

The row decoder 210 is electrically coupled to the word lines WL. The row decoder 210 selects one of the word lines WL and applies word line voltages to the selected word line WL. The word line WL voltages are defined as voltages applied to the selected word line in a writing, erasing and/or reading operation of the flash memory device, which are performed in the non-volatile memory cell 150. According to some embodiments of the present invention, the absolute values of the word line voltages used for the writing and erasing operation is at least greater than a power voltage of the non-volatile memory device. As illustrated in FIG. 1, the row decoder 210 includes a first high-voltage transistor 160a configured to control the word line voltages having high voltages. In some embodiments of the present invention, the row decoder 210 may include a plurality of first high-voltage transistors 160a. A portion of first high-voltage transistors 160a is coupled to the word lines WL.

The reading/writing circuit 220 is coupled to the bit lines BL and configured to select one of the bit lines BL and apply bit line voltages to the selected bit line BL. The bit line voltages are defined as voltages applied to the selected bit line BL in a writing, an erasing and/or a reading operation of the non-volatile memory device, which are performed in the non-volatile memory cell 150. In some embodiments of the present invention, the absolute values of the bit line voltages used in the writing and erasing operations are at least greater than a power voltage of the non-volatile memory device. As illustrated in FIG. 1, the reading/writing circuit 220 includes a second high-voltage transistor 160b configured to control the bit line voltages.

In some embodiments of the present invention, the maximum value of the absolute values of the bit line voltages for controlling the second high-voltage transistor 160b is lower than the maximum value of the absolute values of word line voltages for controlling the first high-voltage transistor 160a. Accordingly, when the same gate voltage is applied to the first and second high-voltage transistors 160a and 160b, a saturation current output per a unit channel width of the second high-voltage transistor 160b may be larger than a saturation current per the unit channel width of the first high-voltage transistor 160a.

As further illustrated in FIG. 1, the reading/writing circuit 220 may include a plurality of second high-voltage transistors 160b. The reading/writing circuit 220 may further include a pass gate PG coupled to the bit line BL, a column decoder CD configured to select the pass gate PG, a sense amplifier SA configured to amplify data output by the pass gate PG, and a writing driving circuit WD configured to apply the bit line voltages used for a writing operation of the bit line BL. The pass gate PG includes the second high-voltage transistor 160b. However, in some embodiments of the present invention, the second high-voltage transistor 160b may be included in the column decoder CD or the writing driving circuit WD.

The low-voltage circuit 230 includes a low-voltage transistor 160c. In some embodiments of the present invention, both the row decoder 210 and the reading/writing circuit 220 may include a low-voltage transistor 160c. In some embodiments of the present invention, the low-voltage transistor 160c may be driven by a power voltage of the non-volatile memory device. In further embodiments of the present invention, the low-voltage transistor 160c may be driven by a voltage lower than the power voltage of the non-volatile memory device.

Operations of the non-volatile memory device will now be discussed. In particular, during a writing operation of the non-volatile memory device, the row decoder 210 selects one of the word lines WL and applies a write word line voltage to the selected word line WL. The absolute value of the write word line voltage is greater than that of a power voltage of the non-volatile memory device. In some embodiments of the present invention, the write word line voltage may be about 10V or any other voltage that is high relative to the power voltage. The reading/writing circuit 220 selects one of the bit lines BL and applies a write bit line voltage to the selected bit line BL. The absolute value of the write bit line voltage is greater than that of a power voltage. The write bit line voltage may be about 5V, which is lower than the write word line voltage. The write bit line voltage is greater than the power voltage and also may be any high voltage lower than the write word line voltage. A programming back bias voltage and a ground voltage are respectively applied to a well and a source region of the non-volatile memory, which are coupled to the selected word line WL and the selected bit line BL. The programming back bias voltage may be about 0.5V. Data is stored in a cell selected by the selected word line WL and the selected bit line BL. At this time, data may be stored in the selected memory cell 150 by, for example, a hot carrier implantation method. In other words, due to the write bit line voltage, charges occur by the hot carriers around a drain region D of the selected memory cell 150. The charges create a tunnel insulating layer of the selected cell 150 by the write word line voltage and are implanted into the storage node SN.

During an erasing operation of the selected cell 150, the row decoder 210 applies an erase word line voltage to the selected word line WL. An erasing back bias voltage is applied to a well of the selected cell 150. At this time, the selected bit line BL and a source region S of the selected cell 150 are floated. The erasing word line voltage has an absolute value that is greater than a power voltage of the non-volatile memory device. For example, the erase word line voltage may be about 11V. The erasing back bias voltage has an absolute value that is also greater than a power voltage of the non-volatile memory device. In some embodiments of the present invention, the absolute value of the erasing bias voltage is lower than the absolute value of the erasing bias voltage of the erase word line voltage. For example, the erasing back bias voltage may be about 6V. Now that the selected bit line BL is floated, it may be boosted by the erasing bias voltage. Thus, charges in the storage node SN of the selected cell 150 create a tunnel insulating layer so as to discharge the storage node SN to the well. Accordingly, the charges can create the tunnel insulating layer using, for example, the Fowler-Nordheim method.

During a reading operation of the selected cell 150, the row decoder 210 applies a read word line voltage to the selected word line WL. The reading/writing circuit 220 applies a read bit line voltage for providing a reference current to the selected bit line BL. The read word line voltage has a value between a threshold voltage of the selected cell 150 when charges in the storage node SN are discharged and a threshold voltage of the selected cell 150 when charges in the storage node SN are stored. In some embodiments of the present invention, the read bit line voltage is lower than the maximum value of the absolute values of the word line voltages. For example, the read bit line voltage may be, for example, equal to a power voltage or to half of the power voltage. Thus, according to whether data of the selected cell 150 is stored, the sense amplifier SA senses a variation of an amount of the reference current supplied to the selected bit line BL so as to read data of the selected cell 150.

As discussed above, in the non-volatile memory devices of FIG. 1, a maximum value of the absolute value of bit line voltages controlled by the second high-voltage transistor 160b is greater than that of a power voltage and lower than that of the first high-voltage transistor 160a. When the same gate voltage is applied to both the bit line and the word line, a saturation current output per a unit channel width of the second high-voltage transistor 160a is larger than a saturation current output per the unit channel width of the first high-voltage transistor 160a. Accordingly, a sensing margin and speed of a read operation of memory devices according to embodiments of the present invention may be improved. In other words, when a relatively low gate voltage in comparison with the maximum value of the word line voltages is applied, the second high-voltage transistor 160b can output a great deal of saturation current as compared to the first high-voltage transistor 106a. Accordingly, the reading/writing circuit 220 according to some embodiments of the present invention can provide a sufficient reference current in a reading operation, so that a sensing margin of the memory device can be improved. In particular, in embodiments of the present invention where the non-volatile memory cell 150 is a multi-level cell, the effect of the improved sensing margin is clear. Furthermore, since the reading/writing circuit 220 can produce the reference current rapidly due to a large amount of saturation current of the second high-voltage transistor 160b, a high-speed non-volatile memory device may be provided. The first and second high-voltage transistors 160a and 160b have a structure, which can sustain a maximum value of the absolute values of the word line voltages and the bit line voltages. Furthermore, the second high-voltage transistor 160b may have a structure having small plane area relative to the first high-voltage transistor 160a due to the relatively high saturation current of the second high-voltage transistor 160b. Thus, a sensing margin of the non-volatile memory cell may be improved and a highly integrated non-volatile memory device capable of high-speed operation may be provided.

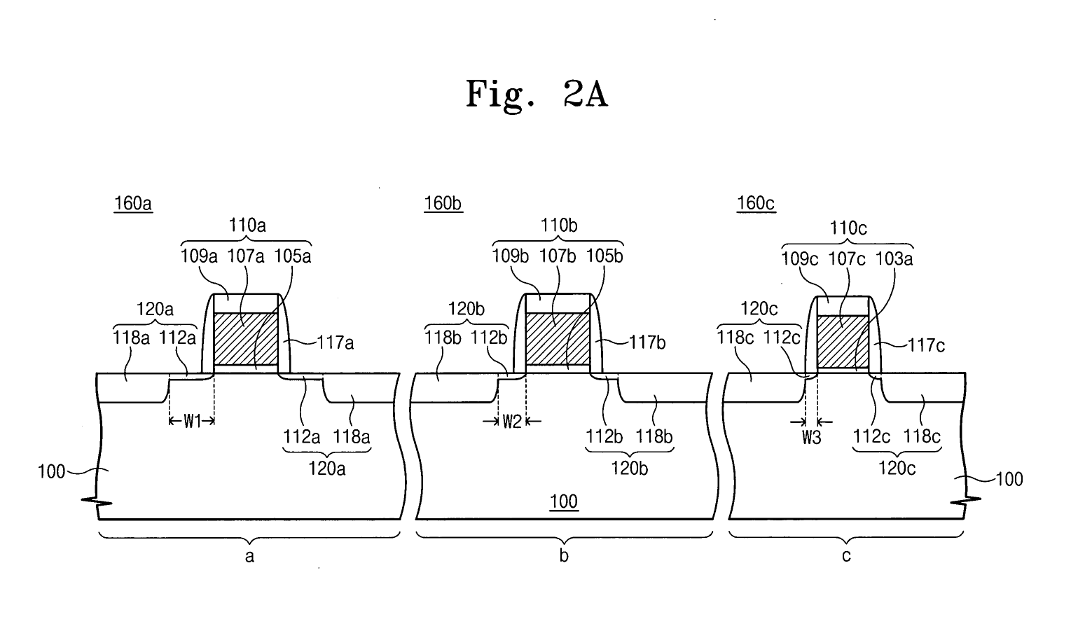

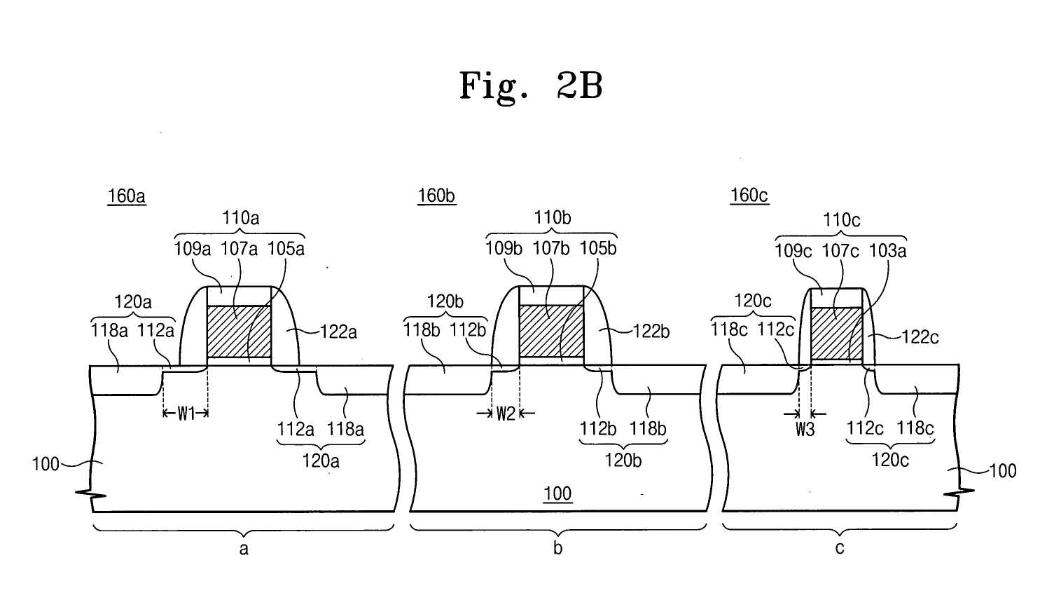

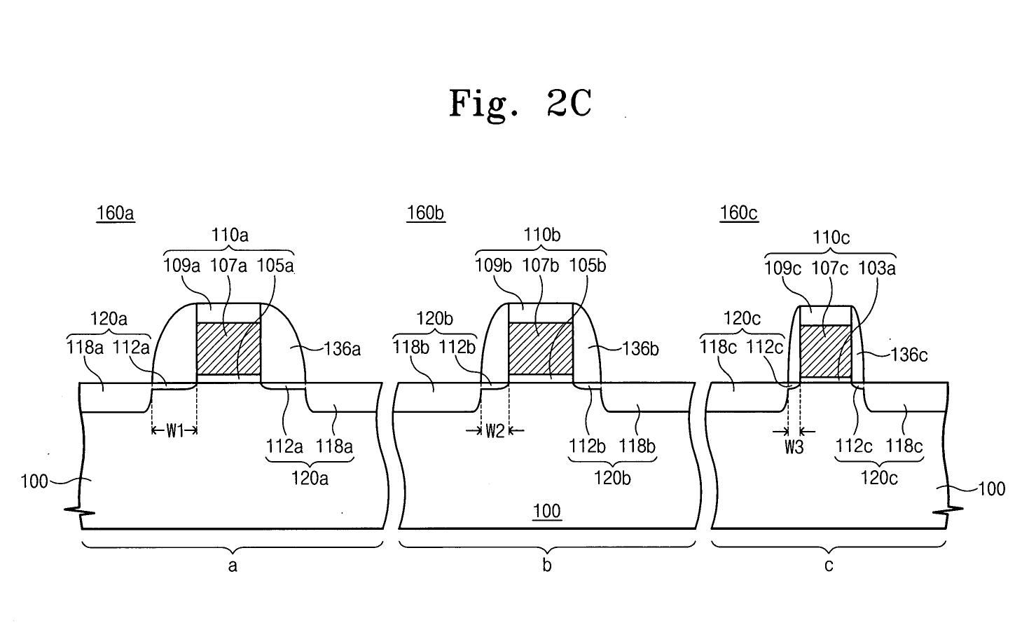

Referring now to FIG. 2A, a cross section illustrating non-volatile memory devices according to some embodiments of the present invention will be discussed. A first high-voltage region, a second high-voltage region and a low-voltage region are denoted by reference numerals “a”, “b” and “c”, respectively. As illustrated in FIGS. 1 and 2A, a substrate 100 includes a high-voltage region (a), a second high-voltage region (b) and a low-voltage region (c). A first high-voltage transistor 160a is provided in the first high-voltage region (a), a second high-voltage transistor 160b is provided in the second high-voltage region (b), and a low-voltage transistor 160c is provided in the low-voltage region (c). In some embodiments of the present invention, the first high-voltage region (a) is provided in a row decoder 210, the second high-voltage region (b) is provided in the reading/writing circuit 220, and the low-voltage region (c) may be provided in the row decoder 210 or the reading/writing circuit 220.

The transistors 160a, 160b and 160c may be, for example, negative-channel metal oxide semiconductor (NMOS) transistors or positive-channel metal oxide semiconductor (PMOS) transistors. Furthermore, the row decoder 210 may include an NMOS-type first high-voltage transistor 160a and a PMOS-type second high-voltage transistor 160a. Similarly, the reading/writing circuit 220 may include an NMOS-type second high-voltage transistor 160b and a PMOS-type second high-voltage transistor 160b. The low-voltage circuit 230 may also include a NMOS-type low-voltage transistor 160c and a PMOS-type low-voltage transistor 160c.

The first high-voltage transistor 160a includes a first high-voltage gate pattern 110a and first source/drain regions 120a. The first high-voltage gate pattern 110a is provided on the substrate 100 of the first high-voltage region (a), and the first source/drain regions 120a are provided on the substrate 100 on both sides of the first high-voltage gate pattern 110a. The high-voltage gate pattern 110a includes a first high-voltage gate insulating layer 105a, a first high-voltage gate electrode 107a and a first capping pattern 109a, which are sequentially stacked. The first source/drain regions 120a include a first low-concentration diffusion layer 112a and a first high-concentration diffusion layer 118a. The first source/drain regions 120a may have a lightly doped drain (LDD) structure. When the first high-voltage transistor 160a is turned on, the first low-concentration diffusion layer 112a is connected to a first high-voltage channel region under the first high-voltage gate pattern 160a. The first high-concentration diffusion layer 118a is isolated from the first high-voltage gate pattern 110a by a first width W1 of the first low-concentration diffusion layer 112a located between the first high-voltage gate pattern 110a and the first high-concentration diffusion layer 118a.

As further illustrated in FIG. 2A, the second high-voltage transistor 160b includes a second high-voltage gate pattern 10b provided on the substrate 100 of the second high-voltage region (b) and second source/drain regions 120b provided on the substrate 100 on both sides of the second high-voltage gate pattern 100. The second high-voltage gate pattern 110b includes a second high-voltage gate insulating layer 105b, a second high-voltage gate electrode 107b and a second capping pattern 109b, which are sequentially stacked. The second source/drain regions 120b include a second low-concentration diffusion layer 112b and a second high-concentration diffusion layer 118b. The second source and drain regions 120b may have an LDD structure. When the second high-voltage transistor 160b is turned on, the second low-concentration diffusion layer 112b is electrically coupled to a second high-voltage channel region under the second high-voltage gate pattern 110b. The length of the second high-voltage channel region may be the same as that of the first high-voltage channel region. The second high-concentration diffusion layer 118b is isolated from the second high-voltage gate pattern 110b by as much as a second width W2 of the second low-concentration diffusion layer located between the second high-voltage gate pattern 110b and the second high-concentration diffusion layer 118b.

In some embodiments of the present invention, a thickness of the first high-voltage gate insulating layer 105a may be the same as a thickness of the second high-voltage gate insulating layer 105b. The first and second high-voltage gate insulating layers 105a and 105b may be thicker than the low-voltage gate insulating layer 103a.

The first low-concentration diffusion layer 112a and the second low-concentration diffusion layer 112b are doped with impurities of the same type. The impurity-concentration of the first and second low-concentration diffusion layers 112a and 112b may also be the same. Similarly, the first and second high-concentration diffusion layers 118a and 118b are doped with impurities of the same type and the concentration of the first high-voltage diffusion layer may also be the same as that of the second high-voltage diffusion layer 118b.

In some embodiments of the present invention, the width W2 of the second low-concentration diffusion layer 112b may be narrower than the width W1 of the first low-concentration diffusion layer 112a. Accordingly, a saturation current per a unit channel width of the second high-voltage transistor 160b may be larger than a saturation current per a unit channel width of the first high-voltage transistor 160a. The first low-concentration diffusion layer 112a acts as a resistance between the first high-voltage channel region and the first high-concentration diffusion layer 118b, and the second low-concentration diffusion layer 112b acts as a resistance between the second high-voltage channel region and the second high-concentration diffusion layer 118b. The width W2 of the second low-concentration diffusion layer 112b is narrower than the width W1 of the first low-concentration diffusion layer 112a, thus, it may be possible to output a saturation current larger than the first high-voltage transistor 160a. As a result, a sensing margin of a non-volatile memory device may be improved.

Since the width W2 of the second low-concentration diffusion layer 112b may be narrow, a plane area of the second high-voltage transistor 160b may be decreased. Due to a large saturation current, the width of the second high-voltage channel region may be narrower than the width of the first high-voltage channel region. Accordingly, it may be possible to provide a highly-integrated non-volatile memory device by decreasing the plane area of the reading/writing circuit 220 of the non-volatile memory device according to some embodiments of the present invention.

As the width W2 of the second low-concentration diffusion layer 112b is decreased, a punch-through voltage between the second source/drain regions 120b may be lower than a punch-through voltage of the first source/drain regions 120a. However, the maximum value of absolute values of bit line voltages that can be applied to the second high-voltage transistor 160b is lower than that of the first high-voltage transistor 160a, so that the second high-voltage transistor 160b may sustain high bit line voltages. The punch-through voltage may be equivalent to a voltage that is applied to a drain region and provide a punch-through phenomenon between the source/drain regions of the turned-off transistor.

As further illustrated in FIG. 2A, the low-voltage transistor 160c includes a low-voltage gate pattern 110c on the substrate 100 of the low-voltage region (c) and third source/drain regions 120c formed at the substrate 100 on both sides of the low-voltage gate pattern 110c. The low-voltage gate pattern 110c includes a low-voltage gate insulating layer 103a, a low-voltage gate electrode 107c and a third capping pattern 109c, which are sequentially stacked on the substrate. The third source/drain regions 120c include a third low-concentration diffusion layer 112c and a third high-concentration diffusion layer 118c, which are arranged in an order from one sidewall of the low-voltage gate pattern 110c. The third high-concentration diffusion layer 118c is isolated from the low-voltage gate pattern 10c by as much as the third width W3. The third width W3 may be defined as the width of the third low-concentration diffusion layer 112c located between the low-voltage gate pattern 110c and the third high-concentration diffusion layer 118c. In some embodiments of the present invention, the first and second widths W1 and W2 of the first and second low-concentration diffusion layers 112a and 112b, respectively, may be wider than the width W3 of the third low-concentration diffusion layer 112c. In other words, the second width W2 of the second low-concentration diffusion layer may be wider than the third width W3 of the third low-concentration layer 112c and may be narrower than the first width W1 of the first low-concentration diffusion layer 112a. The length of a low-voltage channel region under the low-voltage gate pattern 110c may be shorter than that of the first and second high-voltage channel regions.

First, second and third spacers 117a, 117b and 117c are provided on both sidewalls of the first high-voltage gate pattern 110a, the second high-voltage gate pattern 110b and the low-voltage gate pattern 110c, respectively. The widths of bottom surfaces adjacent the substrate 100 of the first, second and third spacers 117a, 117b and 117c may be substantially equal. At this time, the third low-concentration diffusion layer 112c is aligned on the bottom surface of the third spacer 117c. Accordingly, the first and second widths W1 and W2 of the first and second low-concentration diffusion layers 112a and 112b, respectively, are wider than those of the bottom surfaces of the first and second spacers 117a and 117b.

Referring now to FIG. 2B, a cross-sectional view illustrating non-volatile memory devices according to further embodiments of the present invention will be discussed. Like numbers refer to like elements discussed with respect to FIG. 2A and, therefore, will not be discussed in detail further herein. As illustrated in FIG. 2B, first, second and third spacers 122a, 122b and 122c are provided on both sidewalls of a first high-voltage gate pattern 110a, a second high-voltage gate pattern 110b and a low-voltage gate pattern 110c, respectively. The first width W1 of the first low-concentration diffusion layer 112a is wider than the width of a bottom surface of the first spacer 122a. Furthermore, the second low-concentration diffusion layer 112b is aligned on a bottom surface of the second spacer 122b, and the third low-concentration diffusion layer 112c is aligned on a bottom surface of the third spacer 122c. The widths of bottom surfaces of the first and second spacers 122a and 122b are equal, and the widths of bottom surfaces of the first and second spacers 122a and 122b are wider than the width of a bottom surface of the third spacer 122c.

Referring now to FIG. 2C, a cross-sectional view illustrating non-volatile memory devices according to still further embodiments of the present invention will be discussed. Like numbers refer to like elements discussed with respect to FIG. 2A and, therefore, will not be discussed in detail further herein. As illustrated in FIG. 2C, first, second and third spacers 136a, 136b and 136c are arranged on both sidewalls of a first high-voltage gate pattern 110a, a second high-voltage gate pattern 110b and a low-voltage gate pattern 110c, respectively. At this time, the first, second and third low-concentration diffusion layers 112a, 112b and 112c are aligned on bottom surfaces of the first, second and third spacers 136a, 136b and 136c. A width of a bottom surface of the first spacer 136a is wider than widths of the bottom surfaces of the second and third spacers 136b and 136c. The width of a bottom surface of the second spacer 136b is narrower than that of the first spacer 136a and is wider than that of the third spacer 136c.

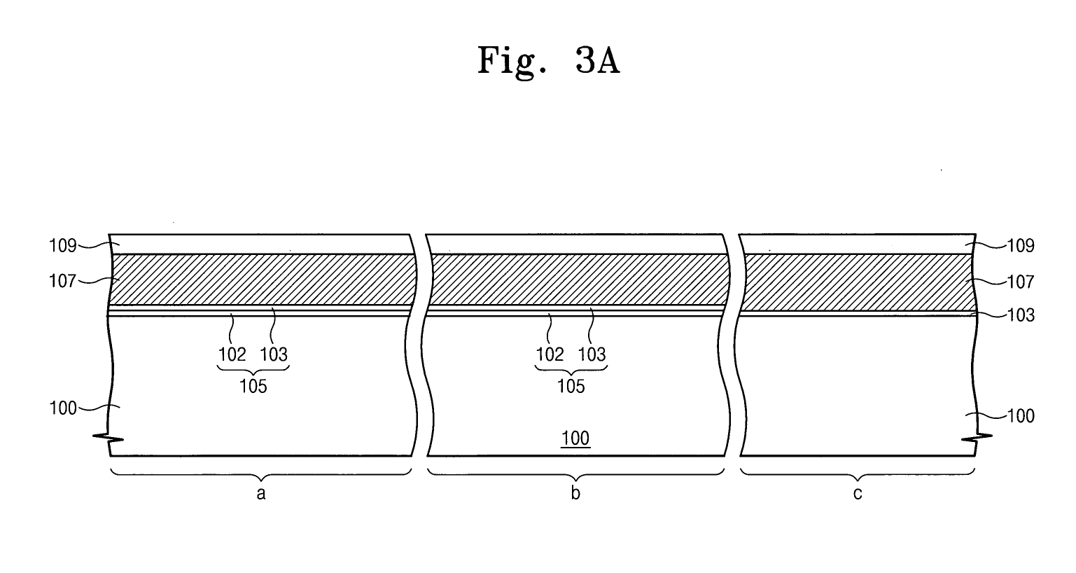

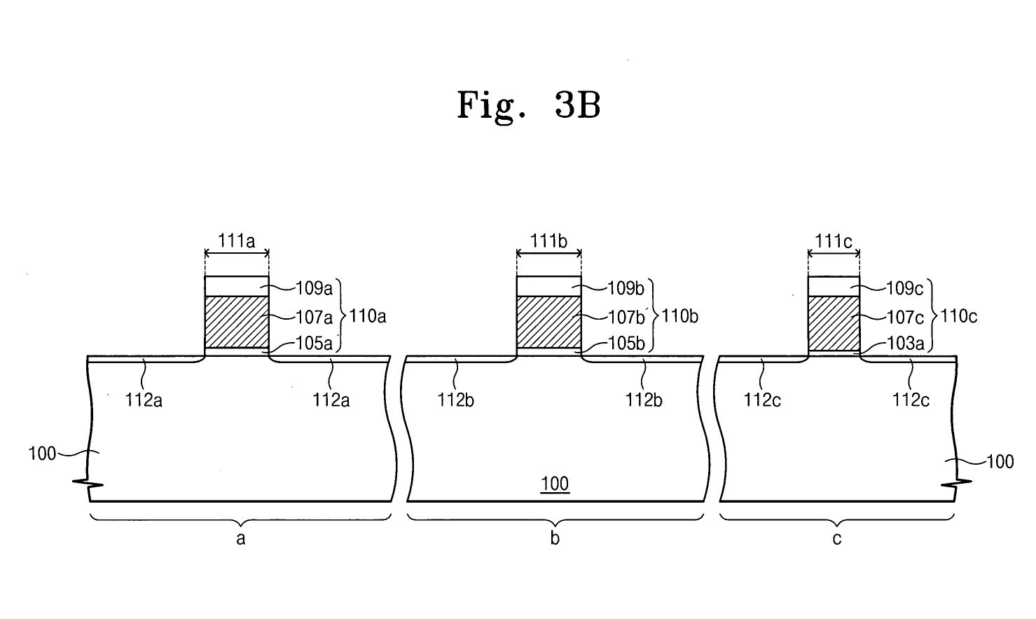

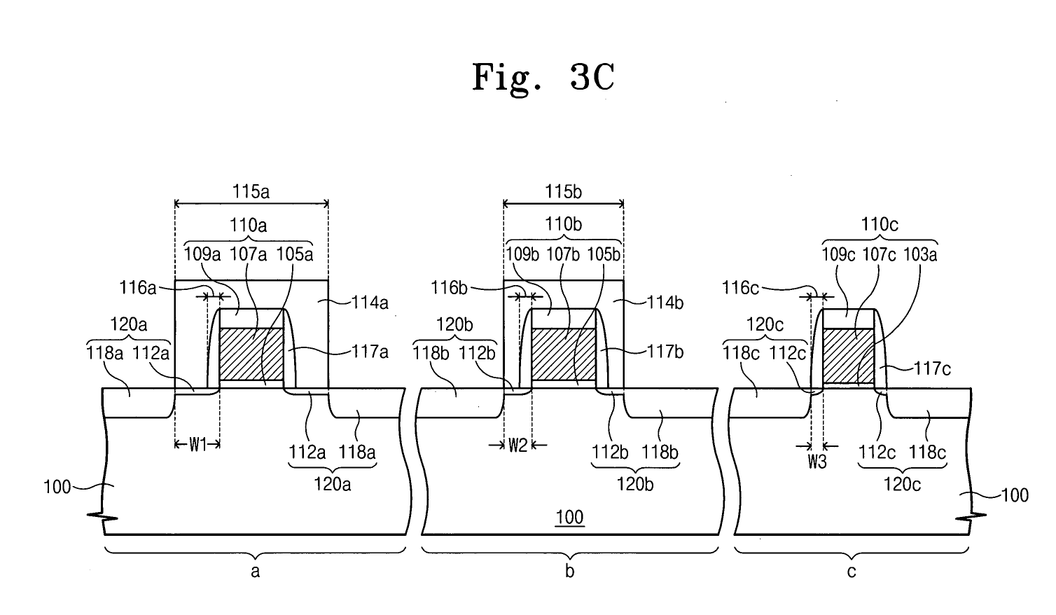

FIGS. 3A to 3C are cross sections illustrating processing steps in the fabrication of non-volatile memory devices according to embodiments of the present invention illustrated in FIG. 2A. Referring now to FIG. 3A, a first insulating layer 102 is formed on a substrate 100 including a first high-voltage region (a), a second high-voltage region (b) and a low-voltage region (c). The first insulating layer 102 may include, for example, a silicon oxide layer, such as, a thermal oxidation layer. Before forming the first insulating layer 102, a device isolation layer (not shown) defining active regions is formed on the substrate 100.

The first insulating layer 102 is selectively removed to expose a substrate 100 of the low-voltage region (c). The first insulating layer 102 may remain on the substrate 100 of the first and second high-voltage regions (a) and (b).

A second insulating layer 103 is formed on a surface of the substrate 100. First and second insulating layers 102 and 103 are formed on the substrate 100 of the first and second high-voltage regions (a) and (b). The first and second insulating layers 102 and 103 may be high-voltage insulating layers 105. A second insulating layer 103 formed on the substrate 100 of the low-voltage region (c) may be a low-voltage insulating layer. The second insulating layer 103 may include, for example, a silicon oxide layer. The second insulating layer 103 may include, for example, a thermal oxidation layer 103.

A gate conductive layer 107 and a capping layer 109 are sequentially formed on a surface of the substrate 100 including the second insulating layer 103. The gate conductive layer 107 may include a lower conductive layer for forming a storage node SN of the non-volatile memory cell of FIG. 1 and an upper conductive layer for forming a control gate electrode CG of the non-volatile memory cell of FIG. 1. The gate conductive layer 107 may include, for example, a doped polysilicon material or a conductive material containing metals. The conductive material containing metals may include, for example, a metal, such as tungsten, a conductive nitride metal, such as nitride titanium, nitride tantalum or nitride tungsten or a metallic silicide, such as tungsten silicide, titanium silicide or tungsten silicide. The capping layer 109 includes an insulating layer. For example, the capping layer 109 may include, for example, a silicon oxide layer, a silicon nitride layer or a silicon oxynitride layer.

Referring now to FIGS. 3B and 3C, the capping layer 109, the gate conductive layer 107 and the high-voltage insulating layer 105 are successively patterned to form a first high-voltage gate pattern 110a in the first high-voltage region (a) and a second high-voltage gate pattern 110b in the second high-voltage region (b). The capping layer 109, the gate conductive layer 107 and the second insulating layer 103 are successively patterned to form a low-voltage gate pattern 110c in the low-voltage region (c). The first high-voltage gate pattern 110a, the second high-voltage gate pattern 110b and the low-voltage gate pattern 110c may be formed sequentially or simultaneously without departing from the scope of the present invention.

The high-voltage gate pattern 110a includes a first high-voltage gate insulating layer 105a, a first high-voltage gate electrode 107a and a first capping pattern 109a, which are sequentially stacked. The second high-voltage gate pattern 110b includes a second high-voltage gate insulating layer 105b, a second high-voltage gate electrode 107b and a second capping pattern 109b, which are sequentially stacked. The low-voltage gate pattern 110c includes a low-voltage gate insulating layer 103a, a low-voltage gate electrode 107c and a third capping pattern 109c, which are sequentially stacked.

In some embodiments of the present invention, a first line width 111a of the first high-voltage gate pattern 110a and a second line width 111b of the second high-voltage gate pattern 110b are wider than a third line width 111c of the low-voltage gate pattern 110a. In some embodiments of the present invention, the first and second line widths 111a and 111b may be substantially equal.

Impurity ions are implanted using the first high-voltage gate pattern 110a as a mask to form a first low-concentration diffusion layer 112a on the substrate 100 on both sides of the first high-voltage gate pattern 110a. Impurity ions are also implanted using the second high-voltage gate pattern 110b as a mask to form a second low-concentration diffusion layer 112b on the substrate 100 on both sides of the second high-voltage gate pattern 10b. Similarly, a third low-concentration diffusion layer 112c is formed on the substrate 100 on both sides of the low-voltage gate pattern 110c. The first, second and third low-concentration diffusion layers 112a, 112b and 112c may be formed sequentially or simultaneously without departing from the scope of the present invention. In some embodiments of the present invention, the first, second and third low-concentration diffusion layers 112a, 112b and 112c may have the same impurity concentration. In further embodiments of the present invention, the first and second low-concentration diffusion layers 112a and 112b may have the same impurity-concentration, and the third low-concentration diffusion layer 118c may have a different impurity concentration from the first and second low-concentration diffusion layers 112a and 112b.

First, second and third spacers 117a, 117b and 117c are formed on both sidewalls of the gate patterns 110a, 110b and 110c, respectively. The widths of lower surfaces 116a, 116b and 116c of the first, second and third spacers 117a, 117b and 117c, respectively, may be substantially equal with each other. The spacers 117a, 117b and 117c may include, for example, an insulating layer, such as a silicon oxide layer, a silicon nitride layer or a silicon oxynitride layer.

A first photosensitive pattern 114a may be formed on the first high-voltage gate pattern 110a and the first spacers 117a in the first high-voltage region (a). A second photosensitive pattern 114b may be formed on the second high-voltage gate pattern 110b and the second spacers 117b in the second high-voltage region (b). In some embodiments of the present invention, the width of 115a of the first photosensitive pattern 114a is wider than a sum of a first line width 111a of the first high-voltage gate pattern 110a and line widths 116a of the first spacers 117a. In some embodiments of the present invention, the width 115b of the second photosensitive pattern 114a is wider than a sum of a second line width 111b of the second high-voltage gate pattern 110a and line widths 116b of the second spacers 117b. In these embodiments of the present invention, the width 116b of the second photosensitive pattern 114a is narrower than the width 115a of the first photosensitive pattern 114a.

Impurity ions are implanted using the first photosensitive pattern 114a as a mask to form a first high-concentration diffusion layer 118a on both sides of the first high-voltage gate pattern 110a. Similarly, impurity ions are implanted using the second photosensitive pattern 114b to form a second high-concentration diffusion layer 118b on both sides of the second high-voltage gate pattern 110b and impurity ions are implanted using the low-voltage gate pattern 110c and third spacers 117c as a mask to form a third high-concentration diffusion layer 118c on both sides of the low-voltage gate pattern 110c. The first, second and third high-concentration diffusion layers 118a, 118b and 118c may be formed sequentially or simultaneously without departing from the scope of the present invention. In some embodiments of the present invention, the high-concentration diffusion layers 118a, 118b and 118c may have the same impurity-concentration. In further embodiments of the present invention, the first and second high-concentration diffusion layers 118a and 118b have the same impurity-concentration, and the third high-concentration layer 118c may have different impurity-concentration from the first and second high-concentration diffusion layers 118a and 118c. The first and second photosensitive patterns 114a and 114b may be removed using, for example, an ashing process.

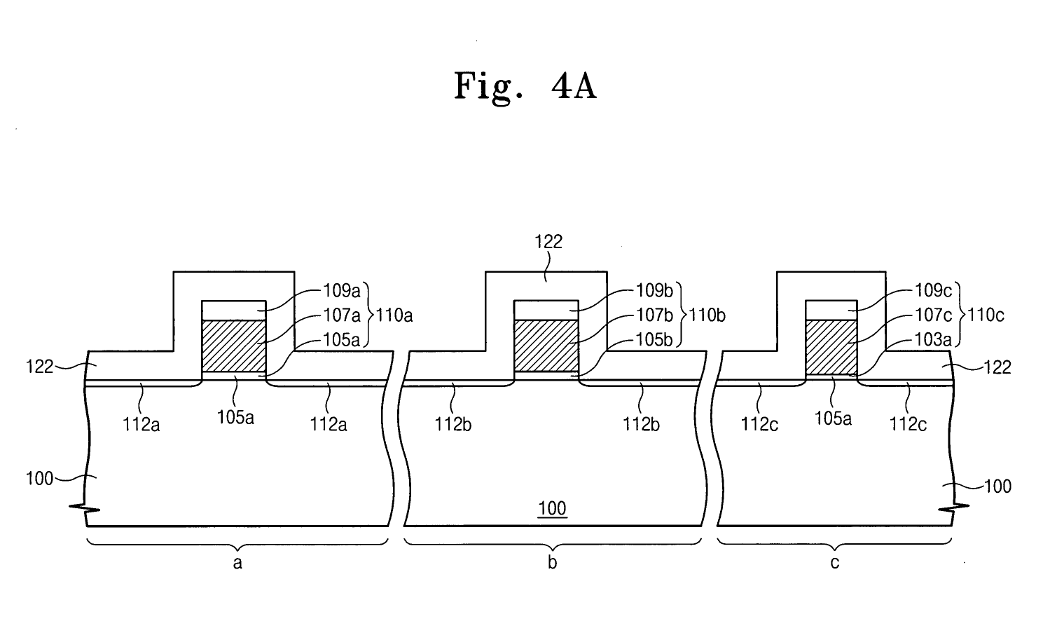

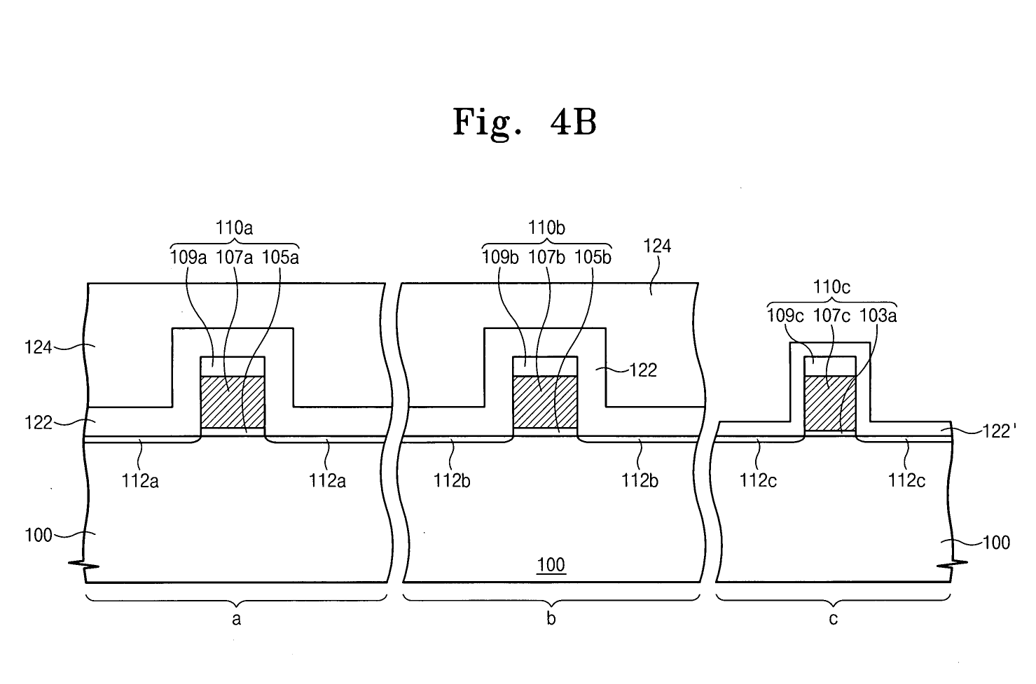

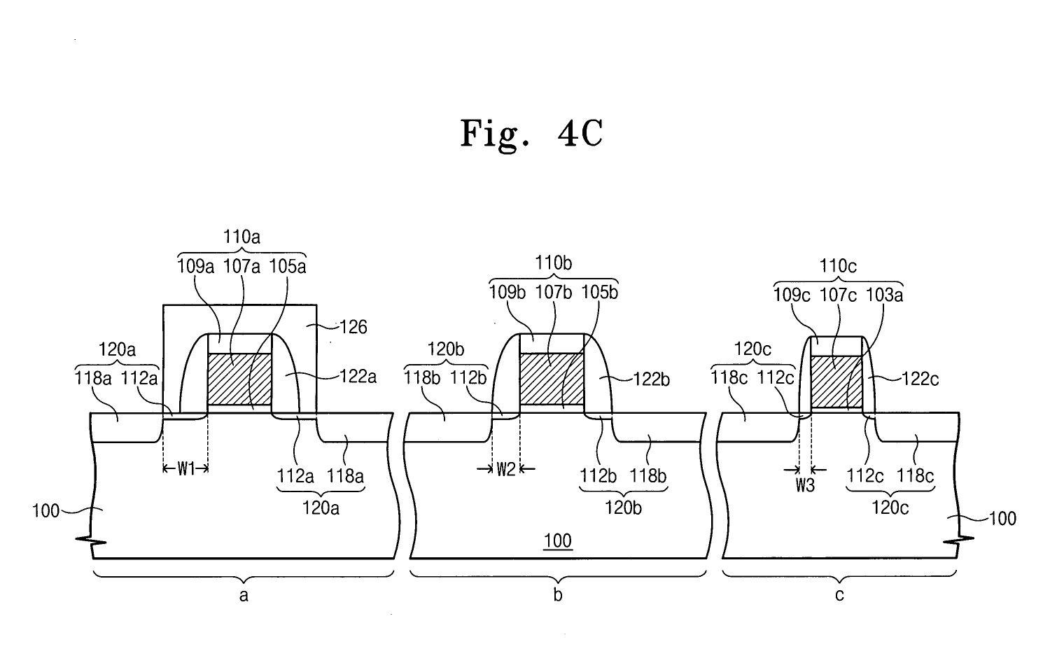

FIGS. 4A to 4C are cross sections illustrating processing steps in the fabrication of non-volatile memory devices according to embodiments of the present invention illustrated in FIG. 2B. The processing steps for forming gate patterns 110a, 110b and 110c, and low-concentration diffusion layers 112a, 112b and 112c can be performed as discussed above with respect to FIGS. 3A and 3B and, therefore, will not be discussed further herein.

Referring now to FIGS. 2B and 4A, a spacer insulating layer 122 is formed on a surface of the substrate 100 having gate patterns 110a, 110b and 110c, and low-concentration diffusion layers 112a, 112b and 112c. The spacer insulating layer 122 may include, for example, an insulating layer, such as a silicon oxide layer, a silicon nitride layer or a silicon oxynitride layer.

Referring now to FIGS. 4B and 4C, a first photosensitive pattern 124 exposing at least a portion of the spacer insulating layer 122 in the low-voltage region (c) is formed on the spacer insulating layer 122. The first photosensitive pattern 124 is formed on the spacer insulating layer 122 in the first and second high-voltage regions a and b. A portion of the exposed spacer insulating layer 122 is recessed using the first photosensitive pattern 124 as a mask. The exposed spacer insulating layer 122 may be recessed using, for example, an isotropic etch process. Accordingly, the recessed spacer insulating layer 122′ may be thinner than the spacer insulating layer 122 in the high-voltage regions (a) and (b) as illustrated in FIG. 4B. The first photosensitive pattern 124 may be removed using, for example, an ashing process, to expose at least a portion of a spacer insulating layer 122 in the high-voltage regions (a) and (b).

Surfaces of the exposed spacer insulating layer 122 and the recessed spacer insulating layer 122′ may be anisotropically etched to respectively form first, second and third spacers 122a, 122b and 122c on both sidewalls of the first high-voltage gate pattern 110a, the second high-voltage gate pattern 10b and the low-voltage gate pattern 110c. As illustrated in FIG. 4C, the widths of bottom surfaces of the first and second spacers 122a and 122b are wider than those of the third spacer 122c.

A second photosensitive pattern 126 is formed on the first high-voltage gate pattern 110a and the first spacers 122a. In some embodiments of the present invention, the second high-voltage gate pattern 100b, the second spacers 122b, the low-voltage gate pattern 110c and third spacers 122c are at least partially exposed. The width of the second photosensitive pattern 126 may be wider than the sum of the line width of the first high-voltage gate pattern 110 and the widths of bottom surfaces of the second spacers 122a.

Impurity ions are implanted using the first photosensitive pattern 126 as a mask to form second high-voltage diffusion layers 118a on the substrate 100 on both sides of the first high-voltage gate pattern 110a. Similarly, impurity ions are implanted using the second high-voltage gate pattern 110b and the second spacers 122b as a mask to form second high-voltage diffusion layers 118b on the substrate 100 on both sides of the second high-voltage gate pattern 100b and impurity ions are implanted using the low-voltage gate pattern 110c and the third spacers 122c as a mask to form third high-voltage diffusion layers 118c on the substrate 100 on both sides of the low-voltage gate pattern 110c. The first, second and third high-concentration diffusion layers 118a, 118b and 118c may be formed sequentially or simultaneously without departing from the scope of the present invention.

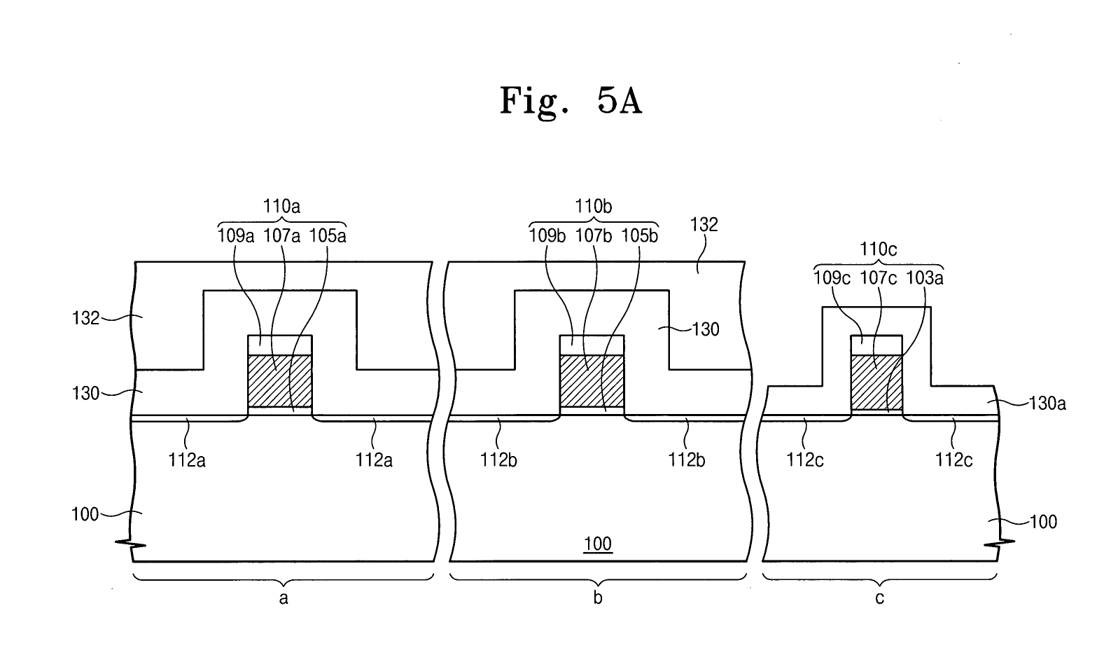

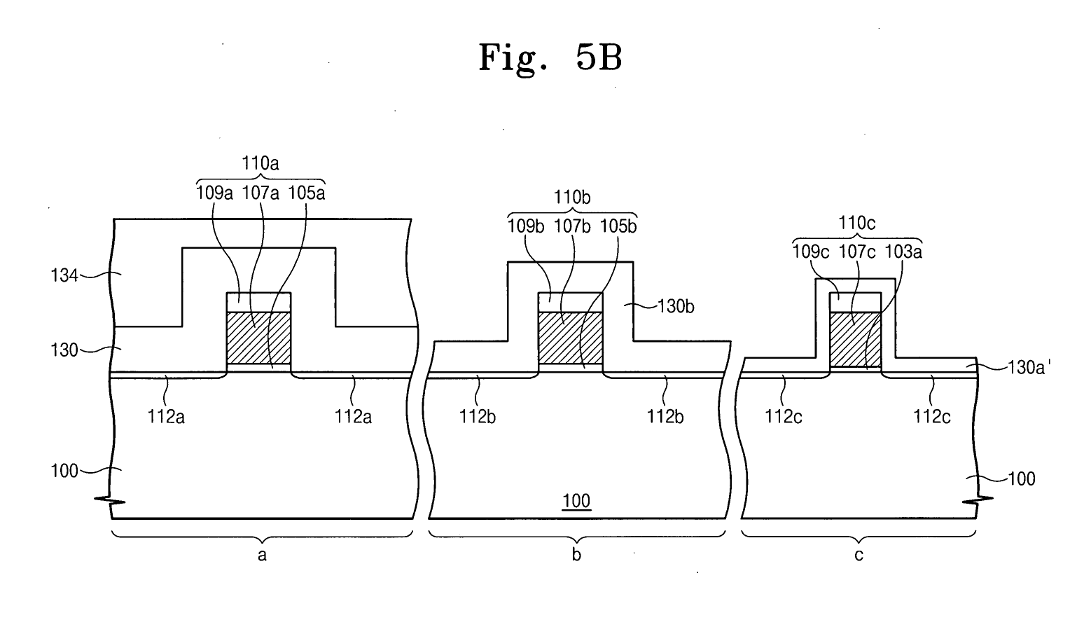

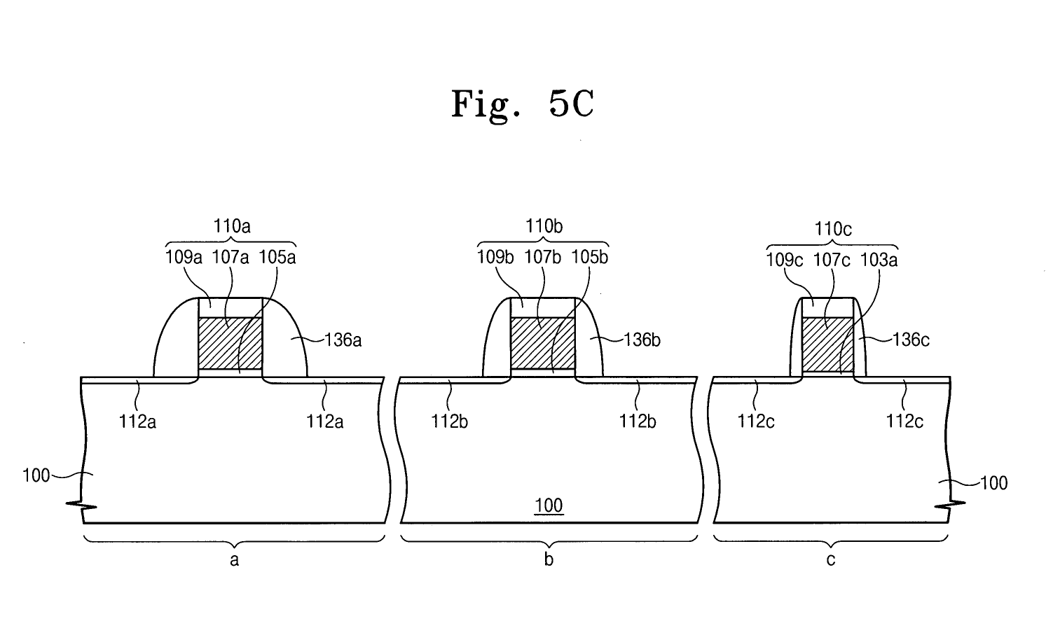

FIGS. 5A through 5C are cross sections illustrating processing steps in the fabrication of non-volatile memory devices according to embodiments of the present invention illustrated in FIG. 2C. Processing steps for fabricating the gate patterns 110a, 110b and 110c, and low-concentration diffusion layers 112a, 112b and 112c are similar to those discussed above with respect to FIGS. 3A through 3C and, therefore, will not be discussed further herein.

Referring to FIGS. 3B and 5A, a spacer insulating layer 130 is formed on the substrate 100 including gate patterns 110a, 110b and 110c, and low-concentration diffusion layers 112a, 112b and 112c. The spacer insulating layer 130 may include, for example, a silicon oxide layer, a silicon nitride layer or a silicon oxynitride layer. As illustrated in FIG. 5A, the spacer insulating layer 130 is thicker than the spacer insulating layer 122 shown in FIG. 4A.

A first photosensitive pattern 132 exposing at least a portion of the spacer insulating layer 130 of a low-voltage region (c) is formed on the spacer insulating layer 130. The first photosensitive pattern 132 is formed on the spacer insulating layer 130 formed on high-voltage regions (a) and (b). A first recess process is performed using the first photosensitive pattern 132 as a mask to recess a portion of the exposed spacer insulating layer 130. The first recess process may be performed using, for example, an isotropic etching process. The first recessed spacer insulating layer 130a is thinner than the spacer insulating layer 130.

Referring now to FIGS. 5B and 5C, the first photosensitive pattern 132 is removed using, for example, an ashing process to expose at least a portion of the spacer insulating layer 130 in high-voltage regions (a) and (b). The first recessed space insulating layer 130a and a second photosensitive pattern 134 exposing the spacer insulating layer 130 in the second high-voltage region (b) are formed on the substrate 100. The second photosensitive pattern 134 is provided on the spacer insulating layer 130 of the first high-voltage region (a).

A second recess process is performed using, for example, the second photosensitive pattern 134 as a mask to recess a portion of the spacer insulating later 130 of the second high-voltage region (b) and the first recessed spacer insulating layer 130a. The second recess process may be, for example, an isotropic etching process. Thus, the thickest spacer insulating layer 130 remains in the first high-voltage region (a), the second recessed spacer insulating layer 130b remains in the second high-voltage region (b) and the recessed spacer insulating layers 130a′ remain in the low-voltage region (c).

The second photosensitive pattern 134 is removed using, for example, an ashing process, to expose at least a portion of the spacer insulating layer 130 of a first high-voltage region (a). A surface of the resultant structure may be anisotropically etched to respectively form first, second and third spacers 136a, 136b and 136c on both sidewalls of the gate patterns 110a, 110b and 110c. The width of a bottom surface of the first spacer 136a is wider than that of second and third spacers 136b and 136c. The width of a bottom surface of the second spacer 136b is narrower than that of the first spacer and is wider than that of the third spacer 136c.

Impurity ions are implanted using the first high-voltage gate pattern 110a and the first spacers 136a as a mask to form first high-voltage diffusion layers 118a of FIG. 2C. Similarly, impurity ions are implanted using the second high-voltage gate pattern 110b and the second spacers 136b as a mask to form second high-voltage diffusion layers 118b of FIG. 2C and impurity ions are implanted using the low-voltage gate pattern 110c and the third spacers 136c as a mask to form third high-voltage diffusion layers 118c of FIG. 2C. The first, second and third high-concentration diffusion layers 118a, 118b and 118c may be formed sequentially or simultaneously without departing from the scope of the present invention.

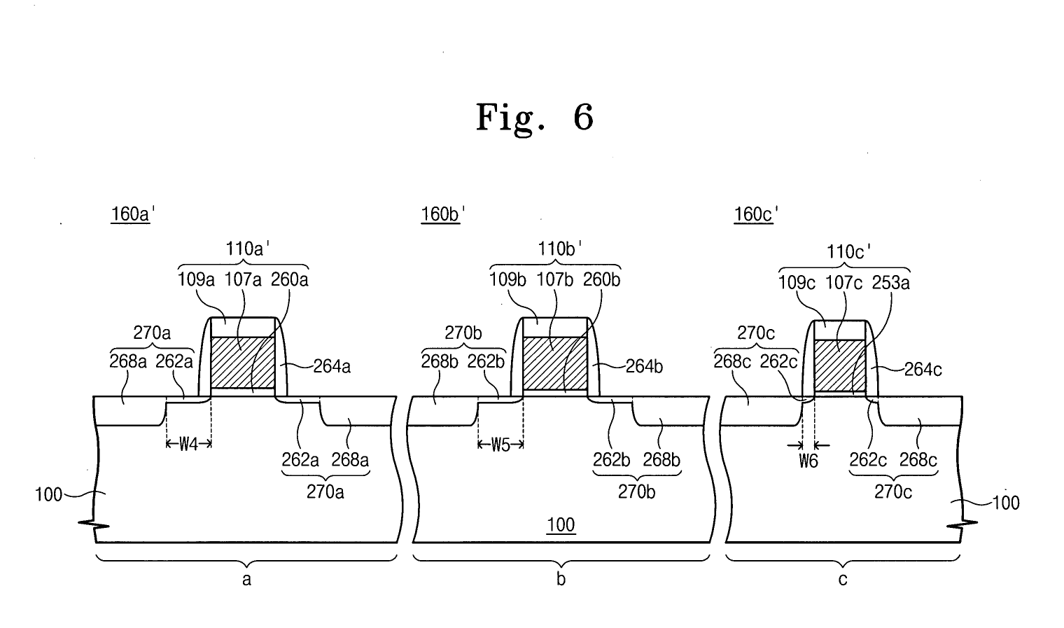

Referring now to FIG. 6, a cross section illustrating non-volatile memory devices according to further embodiments of the present invention will be discussed. Like reference numerals refer to like elements discussed with respect to embodiments of the present invention illustrated in FIGS. 2A through 2C.

As illustrated in FIG. 6, a first high-voltage transistor 160a′ includes a first high-voltage gate pattern 110a′ provided on the substrate 100 of a first high-voltage region (a) and first source/drain regions 270a provided on the substrate 100 on both sides of the first high-voltage gate pattern 110a′. The high-voltage gate pattern 110a′ includes a first high-voltage gate insulating layer 260a, a first high-voltage gate electrode 107a and a first capping pattern 110a′, which are sequentially stacked. The first source/drain regions 270a include a first low-concentration diffusion layer 262a and a first high-concentration diffusion layer 264a. A first spacer 264a is provided on both sidewalls of the first high-voltage gate pattern 110a′ A second high-voltage transistor 160b′ includes a second high-voltage gate pattern 110b′ provided on the substrate 100 of a second high-voltage region (b) and second source/drain regions 270b formed on the substrate 100 at both sides of the second high-voltage gate pattern 110b′. The second high-voltage gate pattern 110b′ includes a second high-voltage gate insulating layer 260b, a second high-voltage gate electrode 107b and a second capping pattern 109b, which are sequentially stacked. The second source/drain regions 270b include a second low-concentration diffusion layer 262b and a second high-concentration diffusion layer 268b. In some embodiments of the present invention, the first and second low-concentration diffusion layers 262a and 262b may have the same width. A second spacer 264b is provided on both sidewalls of the second high-voltage gate pattern 110b′.

A low-voltage transistor 160c′ includes a low-voltage gate pattern 110c′ provided on the substrate 100 of a low-voltage region (c) and third source/drain regions 270c provided on the substrate 100 on both sides of the low-voltage gate pattern 110c′. The low-voltage gate pattern 110c′ includes a low-voltage gate insulating layer 253c, a low-voltage gate electrode 107c and a third capping pattern 109c, which are sequentially stacked. The third source/drain regions 270c include a third low-concentration diffusion layer 262c and a third high-concentration diffusion layer 268c. A third spacer 264c is provided on both sidewalls of the low-voltage gate pattern 110c′.

In some embodiments of the present invention, the second high-voltage gate insulating layer 260b is thinner than the first high-voltage gate insulating layer 260a. Furthermore, the second high-voltage gate insulating layer 260b may be thicker than the low-voltage gate insulating layer 253a. Thus, a threshold voltage of the second high-voltage transistor 160b′ may be lower than a threshold voltage of the first high-voltage transistor 160a′. Accordingly, a saturation current output per a unit channel width of the second high-voltage transistor 160b′ may be larger than that of the first high-voltage transistor 160a′. Furthermore, it may be possible to reduce a plane area of the second high-voltage transistor 160b′ due to the width of a channel region of the second high-voltage transistor 160b′ being narrower. Thus, non-volatile memory devices having first and second high-voltage transistors 160a′ and 160b′ may be highly integrated.

Furthermore, the second high-voltage gate insulating layer 260b may be thicker than the low-voltage gate insulating layer 253a. Accordingly, even if bit line voltages with a high voltage are applied to the second high-voltage transistor 160b′, the second high-voltage gate insulating layer 160b may sustain the high voltage.

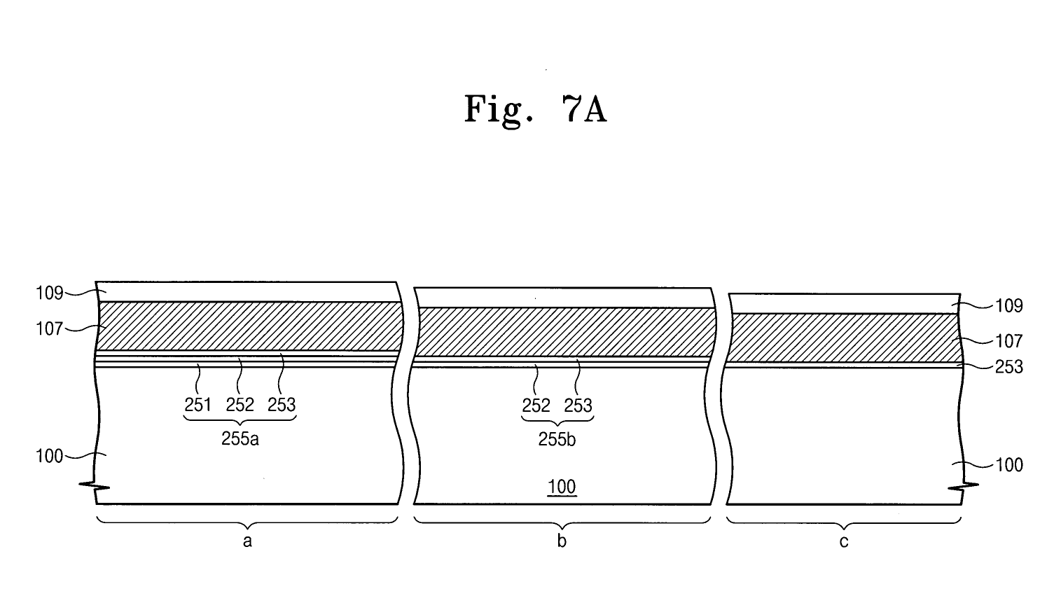

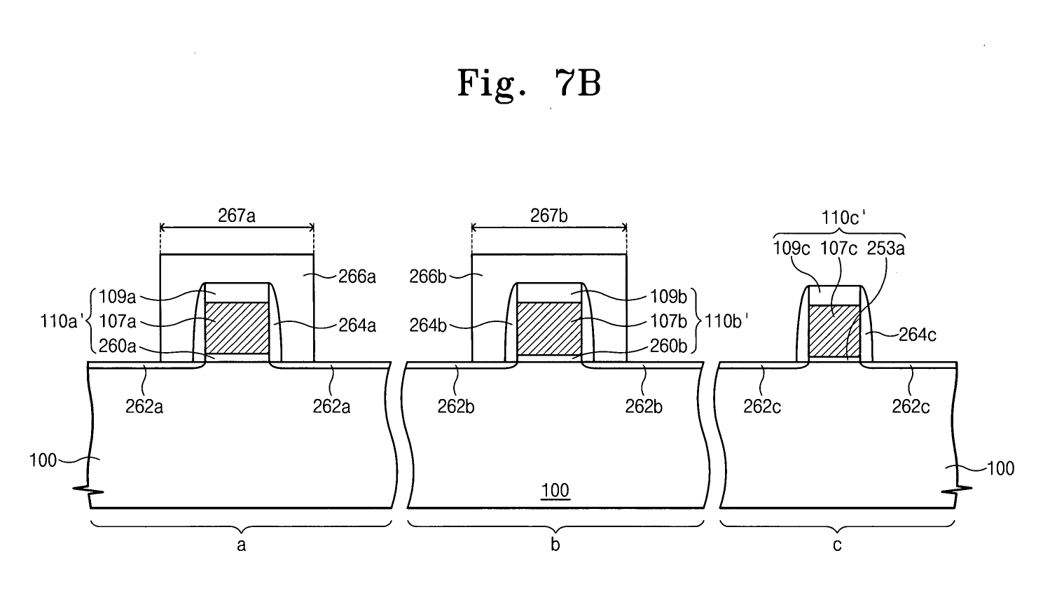

FIGS. 7A and 7B are cross sections illustrating processing steps in the fabrication of integrated circuit according to embodiments of the present invention illustrated in FIG. 6. Referring now to FIGS. 7A and 7B, a first insulating layer 251 is formed on a surface of first and second high-voltage regions (a) and (b), and low-voltage regions (c). The first insulating layer 251 may include, for example, a silicon oxide layer.

The first insulating layer 251 is selectively etched to expose at least a portion of the substrate 100 of the low-voltage region (c) and the substrate 100 of the second high-voltage region (b). A second insulating layer 252 is formed on a surface of the substrate 100. The second insulating layer 252 may include a silicon oxide layer.

The second insulating layer 252 is selectively etched to expose at least a portion of the substrate 100 of the low-voltage region (c). The second insulating layer 252 remains on the substrate 100 of the first and second high-voltage regions (a) and (b) as illustrated in FIG. 7A. A third insulating layer 253 is formed on a surface of the resultant structure. Accordingly, a first high-voltage transistor 255a including first, second and third insulating layers 251, 252 and 253 is formed on the substrate 100 of the first high-voltage region (a), a second high-voltage insulating layer 255b including the second and third insulating layers 252 and 253 is formed on the substrate 100 of the second high-voltage region (b) and only the third insulating layer 253 remains on the substrate 100 of the low-voltage region (c). The third insulating layer 253 may include, for example, a silicon oxide layer.

A gate conductive layer 107 and a capping layer 109 are formed on a surface of the resultant structure. The gate conductive layer 107 and the capping layer 109 may include materials similar to those discussed above with respect to embodiments of the present invention illustrated in FIGS. 2A through 2C. The capping layer 109, the gate conductive layer 107 and the first high-voltage insulating layer 255a are successively patterned to form a first high-voltage gate pattern 110a′ including a first high-voltage gate insulating layer 260a, a first high-voltage gate electrode 107a and a first capping pattern 109a, which are sequentially stacked. The capping layer 109, the gate conductive layer 107 and a second high-voltage gate insulating layer 255b are successively patterned to form a second high-voltage gate insulating layer 110b′ including a second high-voltage gate insulating layer 260b, a second high-voltage gate electrode 107b and a second capping pattern 109b, which are sequentially stacked. The capping layer 109, the gate conductive layer 107 and a third insulating layer 253 are successively patterned to form a low-voltage gate insulating layer 260c, a low-voltage gate electrode 107c and a third capping pattern 109c, which are sequentially stacked. The first and second high-voltage gate patterns 110a′ and 110b′, and the low-voltage gate pattern 110c′ may be formed sequentially or simultaneously without departing from the scope of the present invention.

A first low-concentration diffusion layer 262a is formed on the substrate 100 of both sides of the first high-voltage gate pattern 110a′. A second low-concentration diffusion layer 262b is formed on the substrate 100 on both sides of the second high-voltage gate pattern 110b′. A third low-concentration diffusion layer 262c is formed on the substrate 100 on both sides of the low-voltage gate pattern 110c′. Low-concentration diffusion layers 262a, 262b and 262c may be formed sequentially or simultaneously without departing from the scope of the present invention.

First, second and third spacers 264a, 264b and 264c are formed on both sidewalls of the gate patterns 110a′, 110b′ and 110c′, respectively. In some embodiments of the present invention, the widths of bottom surfaces of the spacers 264a, 264b and 264c may be equal. A first photosensitive pattern 266a is formed on the first high-voltage gate pattern 110a′ and the first spacers 264a, and has a larger line width than the sum of line widths of the first high-voltage gate pattern 110a′ and the first spacers 264a. A second photosensitive pattern 266b is formed on the second high-voltage gate pattern 110b′ and the second spacers 264b, and has a larger line width than the sum of line widths of the second high-voltage gate pattern 110b′ and the second spacers 264b. In some embodiments of the present invention, the line width of the second photosensitive pattern 266b may be narrower than that of the first photosensitive pattern 266a.

Impurity ions are implanted using the first photosensitive pattern 266a as a mask to form a first high-concentration diffusion layer 268a of FIG. 6. Similarly, impurity ions are implanted using the second photosensitive pattern 266b as a mask to form a second high-concentration diffusion layer 268b and impurity ions are implanted using the low-voltage gate pattern 110c′ and third spacers 264c as a mask to form a third high-concentration diffusion layer 268c of FIG. 6. The third high-concentration diffusion layers 268a, 268b and 268c may be formed sequentially or simultaneously without departing from the teachings of the present invention. The first and second photosensitive patterns 266a and 266b may be removed using, for example, an ashing process.

Although embodiments of the present invention are discussed above with respect to NOR-type non-volatile memory devices, embodiments of the present invention are not limited to this configuration. For example, some embodiments of the present invention may be used in NAND-type non-volatile memory devices without departing from the scope of the present invention. Furthermore, aspects of embodiments of the present invention may be combined to create further embodiments not specifically discussed herein. For example, a second high-voltage gate insulating layer 105b may be thinner than a first high-voltage gate insulating layer 105a. Thus, the second high-voltage gate insulating layer 105b may be thicker than a low-voltage gate insulating layer 103a.

As briefly discussed above with respect to FIGS. 1 through 7B, non-volatile memory devices according to some embodiments of the present invention include a first high-voltage transistor configured to control word line voltages and a second high-voltage transistor configured to control bit line voltages. When the same gate voltages are applied to the first and second high-voltage transistors, a saturation current output per a unit channel width of the second high-voltage transistor may be larger than that of the first high-voltage transistor. Thus, according to some embodiments of the present invention, non-volatile memory devices having improved sensing margins and high-speed reading operations may be provided. Furthermore, some embodiments of the present invention may allow further integration of non-volatile memory devices as a plane area of the second high-voltage transistor may be reduced.

In the drawings and specification, there have been disclosed typical preferred embodiments of the invention and, although specific terms are employed, they are used in a generic and descriptive sense only and not for purposes of limitation, the scope of the invention being set forth in the following claims.

1. A non-volatile memory device comprising:
a cell array including a word line and a bit line;
a row decoder coupled to the word line and configured to apply word line voltages to the word line;
a first high voltage transistor coupled to the row decoder configured to control the word line voltages;
a reading/writing circuit coupled to the bit line and configured to apply bit line voltages to the bit line; and
a second high voltage transistor coupled to the reading/writing circuit configured to control the bit line voltages, such that a saturation current output per a unit channel width of the second high-voltage transistor is larger than that of the first high-voltage transistor when a first word line voltage is the same as a first bit line voltage.

2. The device of claim 1, wherein the row decoder is further configured to apply the word line voltages to the word line in a writing, an erasing and/or a reading mode, wherein the reading/writing circuit is further configured to apply the bit line voltages to the bit line in the writing, the erasing and/or the reading mode.

3. The device of claim 2, wherein a maximum value of absolute values of the bit line voltages is less than a maximum value of absolute values of the word line voltages and wherein the maximum value of absolute values of the bit line voltages is greater than a power voltage.

4. The device of claim 1, further comprising an integrated circuit substrate, wherein the first high-voltage transistor comprises:
a first high-voltage gate insulating layer and a first high-voltage gate electrode sequentially stacked on the integrated circuit substrate;
a first source region on the integrated circuit substrate on a first side of the first high-voltage gate electrode; and
a first drain region on the integrated circuit substrate on a second side of the first high-voltage gate electrode, the first source region and the first drain region having a first low-concentration diffusion layer and a first high concentration diffusion layer; and
wherein the second high-voltage transistor includes:
a second high-voltage gate insulating layer and a second high-voltage gate electrode sequentially stacked on the integrated circuit substrate;
a second source region on the integrated circuit substrate on a first side of the second high-voltage gate electrode; and
a second drain region on the integrated circuit substrate on a second side of the second high-voltage gate electrode, the second source region and the second drain region having a second low-concentration diffusion layer and a second high concentration diffusion layer, wherein a width of the second low-concentration diffusion layer is narrower than a width of the first low-concentration diffusion layer.

5. The device of claim 4 further comprising:
a first spacer on sidewalls of the first high-voltage gate electrode; and
a second spacer on sidewalls of the second high-voltage gate electrode, wherein the widths of the first and second low-concentration diffusion layers are wider than widths of bottom surfaces of the first and second spacers.

6. The device of claim 4 further comprising:
a first spacer on sidewalls of the first high-voltage gate electrode; and
a second spacer on sidewalls of the second high-voltage gate electrode, wherein the width of the first low-concentration diffusion layer is wider than a width of a bottom surface of the first spacer and wherein the second low-concentration diffusion layer is aligned to a bottom surface of the second spacer.

7. The device of claim 4, further comprising:
a first spacer on sidewalls of the first high-voltage gate electrode; and
a second spacer on sidewalls of the second high-voltage gate electrode, wherein a width of a bottom surface of the first spacer is wider than a width of a bottom surface of the second spacer and wherein the first and second low-concentration diffusion layers are aligned to the bottom surfaces of the first and second spacers.

8. The device of claim 4, wherein the second high-voltage gate insulating layer is thinner than the first high-voltage gate insulating layer.

9. The device of claim 4, further comprising:
a low-voltage gate insulating layer and a low-voltage gate electrode sequentially stacked on the integrated circuit substrate;
a third source region on the integrated circuit substrate on a first side of the low-voltage gate electrode; and
a third drain region on the integrated circuit substrate on a second side of the low-voltage gate electrode, the third source region and the third drain region having a third low-concentration diffusion layer and third high-concentration diffusion layer, wherein a width of the second low-concentration diffusion layer is wider than a width of the third low-concentration diffusion layer.

10. The device of claim 1, further comprising an integrated circuit substrate, wherein the first high-voltage transistor includes a first high-voltage gate insulating layer and a first high-voltage gate electrode sequentially stacked on the integrated circuit substrate, wherein the second high-voltage transistor includes a second high-voltage gate insulating layer and a second high-voltage gate electrode sequentially stacked on the integrated circuit substrate, and wherein the second high-voltage gate insulating layer is thinner than the first high-voltage gate insulating layer.

11. A NOR-type non-volatile memory device comprising:
an integrated circuit substrate;
a cell array on the integrated circuit substrate and including a word line and a bit line;
a first high-voltage transistor configured to control word line voltages supplied to the word line, the first high-voltage transistor comprising:
a first high-voltage gate insulating layer and a first high-voltage gate electrode sequentially stacked on the integrated circuit substrate; and
a first source region on the integrated circuit substrate on a first side of the first high-voltage gate electrode and a first drain region on the integrated circuit substrate on a second side of the first high-voltage gate electrode, the first source region and the first drain region having a first low-concentration diffusion layer and a first high-concentration diffusion layer; and
a second high-voltage transistor configured to control bit line voltages supplied to the bit line, the second high-voltage transistor comprising:
a second high-voltage gate insulating layer and a second high-voltage gate electrode sequentially stacked on the integrated circuit substrate; and
a second source region on the integrated circuit substrate on a first side of the second high voltage gate electrode and a second drain region on a second side of the second high-voltage gate electrode, the second source region and the second drain region having a second low-concentration diffusion layer and a second high-concentration diffusion layer,
wherein a width of the second low-concentration diffusion layer is narrower than a width of the first low-concentration diffusion layer.

12. The device of claim 11, further comprising
a row decoder configured to apply the word line voltages to the word line; and
a reading/writing circuit configured to apply the bit line voltages to the bit line, wherein the first high-voltage transistor is included in the row decoder and wherein the second high-voltage transistor is included in the reading/writing circuit.

13. The device of claim 12, wherein the row decoder is further configured to apply the word line voltages to the word line in a writing, an erasing and/or a reading mode, wherein the reading/writing circuit is further configured to apply the bit line voltages to the bit line in the writing, the erasing and/or the reading mode.

14. The device of claim 13, wherein a maximum value of absolute values of the bit line voltages is less than a maximum value of absolute values of the word line voltages and wherein the maximum value of absolute values of the bit line voltages is greater than a power voltage.

15. The device of claim 11, further comprising
a first spacer on sidewalls of the first high-voltage gate electrode; and
a second spacer on sidewalls of the second high-voltage gate electrode, wherein the widths of the first and second low-concentration diffusion layers are wider than widths of bottom surfaces of the first and second spacers.

16. The device of claim 11, further comprising
a first spacer on sidewalls of the first high-voltage gate electrode; and
a second spacer on sidewalls of the second high-voltage gate electrode, wherein the width of the first low-concentration diffusion layer is wider than a width of a bottom surface of the first spacer and wherein the second low-concentration diffusion layer is aligned to a bottom surface of the second spacer.

17. The device of claim 11, further comprising
a first spacer on sidewalls of the first high-voltage gate electrode; and
a second spacer on sidewalls of the second high-voltage gate electrode, wherein a width of a bottom surface of the first spacer is wider than a width of a bottom surface of the second spacer and wherein the first and the second low-concentration diffusion layers are aligned to bottom surfaces of the first and second spacers, respectively.

18. The device of claim 11, wherein the second high-voltage gate insulating layer is thinner than the first high-voltage gate insulating layer.

19. The device of claim 11, further comprising:
a low-voltage transistor having a low-voltage gate insulating layer and a low-voltage gate electrode sequentially stacked on the integrated circuit substrate; and
a third source region on the integrated circuit substrate on a first side of the low-voltage gate electrode and a drain region on the integrated circuit substrate on a second side of the low-voltage gate electrode, the third source region and the third drain region having a third low-concentration diffusion layer and a third high-concentration diffusion layer, wherein a width of the second low-concentration diffusion layer is wider than a width of the third low-concentration diffusion layer.

20. A NOR-type non-volatile memory device comprising:
an integrated circuit substrate;
a cell array on the integrated circuit substrate including a word line and a bit line;
a first high-voltage transistor configured to control word line voltages supplied to the word line, the first high-voltage transistor including a first high-voltage gate insulating layer and a first high-voltage gate electrode sequentially stacked on the integrated circuit substrate; and
a second high-voltage transistor configured to control bit line voltages supplied to the bit line, the second high-voltage transistor including a second high-voltage gate insulating layer and a second high-voltage gate electrode sequentially stacked on the integrated circuit substrate, wherein the second high-voltage gate insulating layer is thinner than the first high-voltage gate insulating layer.

21. A method of fabricating a non-volatile memory device comprising:
forming a cell array including a word line and a bit line;
forming a row decoder coupled to the word line and configured to apply word line voltages to the word line;
forming a first high voltage transistor coupled to the row decoder configured to control the word line voltages;
forming a reading/writing circuit coupled to the bit line and configured to apply bit line voltages to the bit line; and
forming a second high voltage transistor coupled to the reading/writing circuit configured to control the bit line voltages, such that a saturation current output per a unit channel width of the second high-voltage transistor is larger than that of the first high-voltage transistor when a first word line voltage is the same as a first bit line voltage.

22. The method of claim 21:
wherein forming the first high-voltage transistor comprises:
forming a first high-voltage gate insulating layer on the integrated circuit substrate;
forming a first high-voltage gate electrode on the first high-voltage gate insulating layer;
forming a first source region having a first low-concentration diffusion layer and a first high-concentration diffusion layer on the integrated circuit substrate on a first side of the first high-voltage gate electrode; and
forming a first drain region having the first low-concentration diffusion layer and the first high-concentration diffusion layer on the integrated substrate on a second side of the first high-voltage gate electrode; and
wherein forming the second high-voltage transistor comprises:
forming a second high-voltage gate insulating layer on the integrated circuit substrate;
forming a second high-voltage gate electrode on the second high-voltage gate insulating layer;
forming a second source region having a second low-concentration diffusion layer and a second high-concentration diffusion layer on the integrated circuit substrate on a first side of the second high-voltage gate electrode; and
forming a second drain region having the second low-concentration diffusion layer and the second high-concentration diffusion layer on the integrated circuit substrate on a second side of the second high-voltage gate electrode, wherein a width of the second low-concentration diffusion layer is narrower than a width of the first low-concentration diffusion layer.

23. The method of claim 22, wherein forming the first and second source and drain regions comprises:
forming the first low-concentration diffusion layer on both sides of the first high-voltage gate electrode;
forming the second low-concentration diffusion layer on the substrate on both sides of the second high-voltage gate electrode;
forming first and second spacers on sidewalls of the first and second high-voltage gate electrodes, respectively;
forming a first photosensitive pattern on the first high-voltage gate electrode and the first spacer, the first photosensitive pattern having a wider width than a sum of widths of the first high-voltage gate electrode and the first spacers;
forming a second photosensitive pattern on the second high-voltage gate electrode and the second spacers, the second photosensitive pattern having a wider width than a sum of the widths of the first high-voltage gate electrode and the second spacers; and
implanting impurity ions using the first and second photosensitive patterns as a mask to form the first and second high-concentration diffusion layers, wherein a width of the second photosensitive pattern is narrower than a width of the first photosensitive pattern.

24. The method of claim 22, wherein forming the first and the second source and drain regions comprises:
forming a first low-concentration diffusion layer on the substrate on both sides of the first high-voltage gate electrode;
forming a second low-concentration diffusion layer on the substrate on both sides of the second high-voltage gate electrode;
forming first and second spacers on sidewalls of the first and second high-voltage gate electrodes, respectively;
forming a photosensitive pattern on the first high-voltage gate electrode and the first spacers, the photosensitive pattern having a wider width than a sum of widths of the first high-voltage gate electrode and the first spacers; and
implanting impurity ions using the photosensitive pattern, the second high-voltage gate electrode and the second spacers as a mask to form the first and second high-concentration diffusion layers.

25. The method of claim 22, wherein the forming the first and the second source and drain regions comprises:
forming a first low-concentration diffusion layer on the substrate on both sides of the first high-voltage gate electrode;
forming a second low-concentration diffusion layer on the substrate on both sides of the second high-voltage gate electrode;
forming first and second spacers on sidewalls of the first and second high-voltage gate electrode, respectively, wherein a width of a bottom surface of the first spacer is wider than a width of a bottom surface of the second spacer; and
implanting impurity ions using the first high-voltage gate electrode and the first spacers, and the second high-voltage gate electrode and the second spacers as a mask to respectively form the first and second high-voltage diffusion layers.

26. The method of claim 22, wherein the second high-voltage gate insulating layer is thinner than the first high-voltage gate insulating layer.

27. The method of claim 22, further comprising:
forming a low-voltage gate insulating layer on the integrated circuit substrate;
forming a low-voltage gate electrode on the low-voltage gate insulating layer;
forming a third source region having a third low-concentration diffusion layer and a third high-concentration diffusion layer on the substrate on a first side of the low-voltage gate electrode; and
forming a third drain region having the third low-concentration diffusion layer and the third high-concentration diffusion layer on the substrate on a second side of the low-voltage gate electrode, wherein the second low-concentration diffusion layer is wider than the third low-concentration diffusion layer.

28. The method of claim 21, wherein forming the first and second high-voltage transistors comprise:
forming a first high-voltage gate insulating layer on the integrated circuit substrate;
forming a first high-voltage gate electrode on the first high-voltage gate insulating layer;
forming a second high-voltage gate insulating layer on the integrated circuit substrate;
forming a second high-voltage gate electrode on the second high-voltage gate insulating layer;
forming first source and drain regions on the substrate on respective first and second sides of the first high-voltage gate electrode; and
forming second source and drain regions on the substrate on respective first and second sides of the second high-voltage gate electrode, wherein the second high-voltage gate insulating layer is thinner the first high-voltage gate insulating layer.
